(19) United States
(12) Patent Application Publication
(10) Pub. No.: US 2005/0124151 A1
(43) Pub. Date: Jun. 9, 2005

(54) Novel method to deposit carbon doped SiO2 films with improved film quality

(75) Inventors: Yi-Lung Cheng, Danshuei Township (TW); Ren-Haur Liu, Hsin-Chu (TW); Cheng-Hsiung Liu, Hsin-Chu (TW); Ying-Lang Wang, Taichung County (TW); Hway-Chi Lin, Hsinchu City (TW); Chien-Ming Chiu, Hsinchu City (TW)

Correspondence Address: DUANE MORRIS, LLP;IP DEPARTMENT, ONE LIBERTY PLACE, PHILADELPHIA, PA, 19103-7396, US

(73) Assignee: Taiwan Semiconductor Manufacturing Co.

(21) Appl. No.: 10/728,215

(22) Filed: Dec. 4, 2003

(51) Int. Cl. H01L 21/4763; H01L 21/31; H01L 21/469

(52) U.S. Cl. 438/623; 438/783; 438/638; 438/780

(57) ABSTRACT

A method is disclosed for depositing a Black Diamond layer in a CVD chamber. Trimethylsilane, O₂, and Ar are flowed into the chamber at 300° C. to 400° C. with an O₂:Ar:trimethylsilane flow rate ratio that is preferably 1:1.5:6. The resulting low k dielectric layer is formed with a higher deposition rate than when Ar is omitted and has a k value of about 3 that increases only slightly in O₂ plasma. A higher density, hardness, and tensile strength are achieved in the Black Diamond layer when Ar is included in the deposition process. The addition of Ar in the deposition maintains film thickness uniformity below 2% for a longer period so that PM cleaning operations are less frequent and affords a lower fluorocarbon plasma etch rate to enable improved trench depth control in a damascene scheme. A lower leakage current and higher breakdown voltage in achieved in the resulting metal interconnect.

### FIELD OF THE INVENTION

The invention relates to the field of fabricating integrated circuits and other electronic devices and in particular to a method of improving the properties of a carbon doped SiO₂ low k dielectric layer that is deposited by a plasma enhanced chemical vapor deposition (PECVD) method.

### BACKGROUND OF THE INVENTION

The fabrication of a high performance electronics device involves the formation of metal interconnects as electrical pathways and the deposition of one or more dielectric layers to insulate one interconnect from another. Metal interconnects are typically trenches, vias, or contact holes that are filled with a metal such as copper. One popular method for forming an interconnect is a damascene process in which an opening is etched in a dielectric layer, a metal is deposited in the opening, and a planarization step such as a chemical mechanical polish (CMP) step is used to make the metal coplanar with the top of the dielectric layer.

A significant amount of attention has been directed in recent years to improving the quality of the dielectric layer that insulates metal interconnects. First, SiO₂ with a dielectric constant (k) of about 4 is being replaced with a low k dielectric material such as carbon doped SiO₂ or fluorine doped SiO₂ that have a k value of about 2.5 to approximately 3. A low k dielectric material has a better ability to prevent crosstalk between conductive layers as the dimension between wiring shrinks in newer devices. Unfortunately, a low k dielectric layer is often porous and may require a treatment to densify the layer in order to prevent water absorption that will increase the effective dielectric constant. Furthermore, the hardness and tensile strength of a low k dielectric layer is a concern since a CMP planarization step can easily cause scratches, peeling, or cracking in a low k dielectric layer that will degrade device performance. Accordingly, increasing the hardness and Young's Modulus of a low k dielectric layer is associated with a lower leakage current and a higher breakdown voltage.

Another important issue is the cost associated with depositing a low k dielectric layer. For example, a carbon doped SiO₂ layer available as Black Diamond from Applied Materials of Santa Clara, Calif., CORAL from Novellus of San Jose, Calif., HOSP from Allied Signal, or by other trade names from other suppliers is generally formed by a PECVD method that includes an organosilicon precursor such as trimethylsilane and an oxidizer (O₂, N₂O, ozone, etc.). Carbon doped SiO₂ is also known as organosilicate glass (OSG) and typically has a hydrogen content as well. Organosilicon precursors are more expensive than silane which is used to form SiO₂. Moreover, the deposition rate of a Black Diamond film is only about half that of SiO₂ formed from SiH₄ and O₂ and the lower deposition rate slows throughput in the manufacturing line. Therefore, a method of depositing a Black Diamond film or the like that requires lesser amounts of expensive organosilicon precursors and which has a relatively high deposition rate is desirable.

An important requirement of a low k dielectric layer is good film thickness uniformity since subsequent processing involves patterning a photoresist layer to form an opening that is etched into the low k dielectric layer. Although one or more intermediate layers may be deposited on the low k dielectric layer before the photoresist layer is formed, a smooth low k dielectric layer enables the formation of a smooth photoresist layer which in turn results in a larger process window for the patterning step. When a low k dielectric layer is deposited on a wafer in a chemical vapor deposition (CVD) process chamber, the low k dielectric material is also deposited on the chamber walls. As the deposition process is repeated hundreds of times and the buildup on the chamber walls increases, the low k dielectric material on the walls appears to adversely influence the film uniformity of the low k dielectric layer deposited on a wafer. Film thickness uniformity degrades from near 1% to about 4% (3σ variation) after approximately 1000 wafers are processed. At this point, the process chamber must be taken out of service for cleaning purposes which decreases throughput. Thus, an improved deposition method is needed that maintains good film uniformity for longer periods of time and reduces the frequency of preventative maintenance.

In U.S. Patent Application Publication 2003/0032292, a Black Diamond film is formed by a process involving trimethylsilane and oxygen. In U.S. Pat. No. 6,372,632, an organosilane such as trimethylsilane and a compensatory gas including Ar, O₂, CH₄, N₂O, N₂, H₂, etc., is employed to deposit a low k dielectric layer. However, neither reference provides process conditions for the low k dielectric layer deposition.

A dual phase dielectric layer in which a first phase is comprised of SiCOH is described in U.S. Pat. No. 6,312,793. The silicon precursor is preferably a ring compound such as TMCTS. An oxidizing agent and optionally He or Ar as carrier gases are used in the deposition.

A silicon oxycarbide layer is deposited in U.S. Pat. No. 6,541,397 with one or more organosilicon compounds, an oxidizing gas, and an inert gas at 50-5000 sccm. However, the prior art does not teach the importance of the relationship between the Ar flow rate and the O₂ and organosilicon flow rates in improving film quality and increasing the deposition rate.

### SUMMARY OF THE INVENTION

An objective of the present invention is to provide a method of depositing a carbon doped SiO₂ layer such as a Black Diamond film that provides a higher deposition rate than conventional CVD methods.

A further objective of the present invention is to provide a method of depositing a carbon doped SiO₂ layer which maintains good film thickness uniformity for a larger number of wafers successively processed in a CVD chamber so that the frequency of preventative maintenance cleaning operations in the CVD chamber may be reduced.

A still further objective of the present invention is to provide a method of depositing a carbon doped SiO₂ layer that has increased hardness and a higher value for tensile strength (Young's modulus).

Yet another objective of the present invention is to provide a method of depositing a carbon doped SiO₂ layer that has better thermal and chemical stability including a higher resistance to O₂ ashing and a lower etch rate in a fluorocarbon based plasma.

These objectives are achieved by providing a substrate and a CVD process chamber. Once the substrate is loaded into the CVD chamber, the chamber is heated to an appropriate temperature and the chamber pressure is reduced to an acceptable level. A low k dielectric layer comprising carbon doped SiO₂ is deposited on the substrate by flowing oxygen, an inert gas which is preferably argon, and an organosilane that is preferably trimethylsilane at a preferred ratio of 1:1.5:6 into the chamber while a plasma is generated. Argon is flowed into the chamber during the PECVD process at a sufficient rate to increase the deposition rate of the carbon doped SiO₂ film and to provide a bombardment effect that densifies, hardens, and improves the tensile strength of the film. High Ar flow rates that increase the dielectric constant of the deposited film and low Ar flow rates that lead to a higher than desired porosity in the film are avoided. The carbon doped SiO₂ film is deposited at a high enough temperature so that a post-deposition anneal is not required. At this point the substrate may be removed or another dielectric layer such as a cap layer or anti-reflective coating (ARC) may be deposited on the carbon doped SiO₂ layer in the CVD process chamber.

In one application, the low k dielectric layer is deposited on an etch stop layer which has been formed on a substrate in a single or dual damascene scheme. Optionally, a cap layer or an ARC is deposited on the low k dielectric layer. A via opening is formed in the low k dielectric layer and a trench is fabricated above the via by a conventional sequence of patterning and etching steps. After an etch step removes the etch stop layer at the bottom of the via, a conformal diffusion barrier layer is deposited in the via and trench followed by deposition of a metal layer to fill the via and trench. A planarization step completes the damascene scheme. The improved physical and mechanical properties of the low k dielectric layer enable a lower leakage current and higher breakdown voltage in the resulting metal interconnect.

### BRIEF DESCRIPTION OF THE DRAWINGS

FIG. 1 is a plot showing the degradation in film uniformity of a deposited carbon doped SiO₂ layer with an increasing number of processed wafers in a chamber between preventative maintenance cleaning operations.

FIG. 2 is a plot that demonstrates an increase in deposition rate for a Black Diamond film when Ar or He are added to O₂ and trimethylsilane in the PECVD process of the present invention.

FIG. 3 is a plot depicting the dielectric constant (k value) of a Black Diamond layer as a function of Ar flow rate in the PECVD method of the present invention.

FIG. 4 is a plot showing a lower leakage current in a device when a conventional Black Diamond dielectric layer is replaced by a Black Diamond dielectric layer formed by incorporating Ar in the deposition process.

FIG. 5 is a cross-sectional view showing the deposition of a carbon doped SiO₂ layer as a low k dielectric layer on a substrate according to a method of the present invention.

FIGS. 6-8 are cross-sectional views that depict plasma etch processes during a dual damascene scheme when the low k dielectric layer of the present invention is exposed to etchants.

FIG. 9 is a cross-sectional view after deposition of a diffusion barrier layer and a metal layer to fill an opening in the low k dielectric layer and a planarization step that lowers the level of the metal layer to be coplanar with the low k dielectric layer.

### DETAILED DESCRIPTION OF THE INVENTION

The invention is a method of depositing a carbon doped SiO₂ film as a low k dielectric layer to insulate metal interconnects in a semiconductor device. The drawings are provided by way of example and are not intended to limit the scope of the invention. Moreover, the figures are not necessarily drawn to scale and the relative size of various elements may be different than found in an actual device. Although FIGS. 5-9 depict the use of an interlevel dielectric layer (ILD) in a damascene scheme for fabricating a metal interconnect, those skilled in the art will appreciate that a carbon doped SiO₂ layer may also be deposited according to a method of the present invention in a gap fill operation (not shown) to form an intermetal dielectric (IMD) layer between metal lines formed on a substrate.

It is understood that the deposition method of the present invention may be performed in any chemical vapor deposition (CVD) process chamber to form a carbon doped SiO₂ layer and that a plasma may be applied to exercise a PECVD process in the CVD process chamber. When the deposition is carried out in an Applied Materials tool such as a DxZ™ or a Producer CVD chamber, the product is generally referred to as a Black Diamond film. Optionally, a CORAL film may be produced by exercising the process in a Novellus CVD chamber or a HOSP film may be generated with an Allied Signal process. As mentioned previously, carbon doped SiO₂ films are known by various trade names depending on the type of CVD process chamber and recipe that is used for the deposition. The final composition of the carbon doped SiO₂ film may vary somewhat but typically contains C, H, Si, and O in all examples. In the preferred embodiment of this invention, any CVD chamber may be selected since the critical requirement for improving the physical and mechanical properties of the resulting low k dielectric layer is the process conditions for depositing the carbon doped SiO₂ film.

Referring to FIG. 1, the inventors have observed that as the number of carbon doped SiO₂ depositions increases in a CVD process chamber after a preventative maintenance (PM) cleaning, the film thickness uniformity of the resulting low k dielectric layer increases from about 1% to 4% or more. In other words, the 3σ film thickness variation is significantly lower for a carbon doped SiO₂ layer deposited on a wafer immediately after a PM cleaning operation than after several hundred wafers have been processed through the chamber without a cleaning step. It is believed that the low k dielectric material which is deposited on the walls of the CVD chamber increases in thickness over time and has a detrimental influence on the uniformity of deposition on an adjacent wafer. After the uniformity level reaches about 3 to 4%, the chamber is taken out of service for PM cleaning. Obviously, an increase in the frequency of PM cleaning reduces throughput and therefore increases the cost of the manufacturing line.

In the preferred embodiment, the method for depositing a carbon doped SiO₂ layer includes dimethylsilane (2MS), trimethylsilane (3MS), or tetramethylsilane (4MS) as a Si source gas and O₂ as an oxygen source gas. After the wafer loaded into a CVD process chamber and is secured to a chuck (not shown) that may also serve as an electrode, the air in the chamber is evacuated with a vacuum pump and the substrate is usually heated to promote the deposition process. When temperature and pressure are stabilized at acceptable levels, the source gases are fed into the process chamber through holes in a showerhead at the top of the chamber, for example, and a plasma is generated such as by applying a RF power, for example. Reactive species including (CH₃)₃Si⁺, CH₃Si⁺³, and oxygen radicals are formed when 3MS and O₂ are selected as source gases. The first step in the deposition process is absorption of the reactive species on a substrate. In some cases, a reactive silicon species and a reactive oxygen species may not be in close enough proximity on a substrate to react. An interval of time is necessary for the reactive species to migrate on the substrate and then react to form a molecule of the low k dielectric material. Eventually, enough low k dielectric material is deposited to form a layer that is usually several thousand Angstroms thick. A high rate of deposition is desired in order to achieve a high wafer throughput in the CVD process chamber.

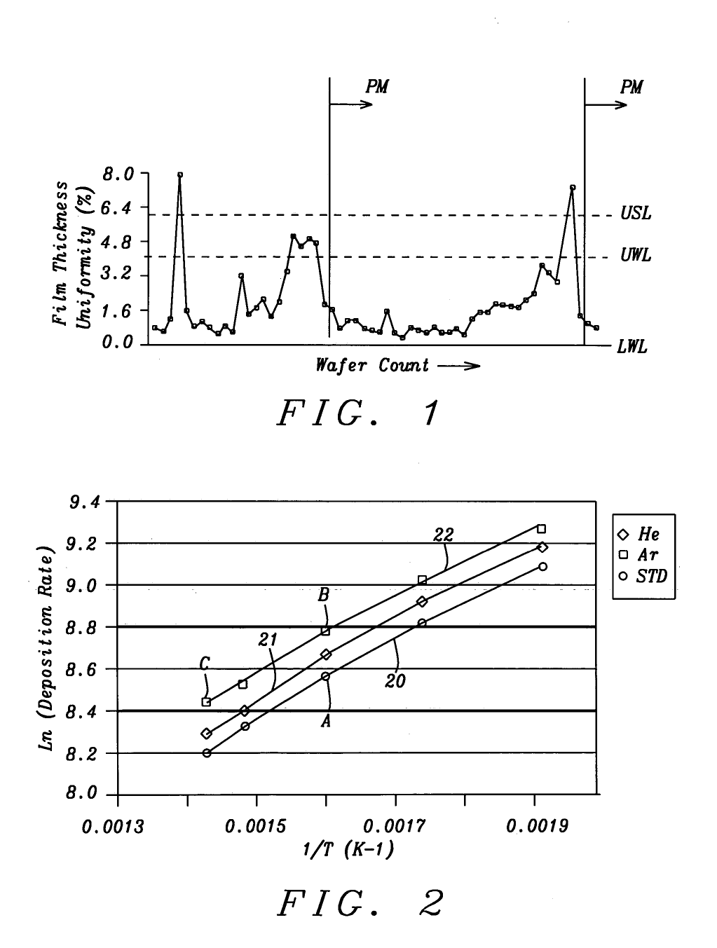

It is well known by those who practice the art that the rate of a chemical reaction usually increases as the concentration of the reactants increases. However, in the example of a PECVD deposited carbon doped SiO₂ layer, the inventors have surprisingly found that by diluting the source gases with an inert gas, the rate of deposition increases. As shown by the curve 20 in FIG. 2, a conventional method of forming a carbon doped SiO₂ layer involving O₂ and trimethylsilane (3MS) yields a deposition rate of 5394 Angstroms/minute (point A) with an O₂ flow rate of 100 standard cubic centimeters per minute (sccm), a 3MS flow rate of 600 sccm, a chamber temperature of 350° C., a RF power of 600 Watts, and a chamber pressure of about 2.5 Torr. Under similar conditions except with an added flow rate of 150 sccm He as depicted in curve 21, the rate increases to 5787 Angstroms/min. and when an added flow rate of 150 sccm Ar is used in place of He as in curve 22, the deposition rate increases further to 6440 Angstroms/min. (point B). Note that the rate on curve 22 decreases as temperature increases to 425° C. (point C). An added benefit is that with a nearly 20% faster deposition rate, the usage of 3MS is reduced by about 20% per wafer which is an appreciable cost savings.

A key feature in the method of this invention is the addition of a sufficient amount of an inert gas which is preferably Ar to the O₂ and 2MS, 3MS, or 4MS source gases in the CVD process chamber such that an improvement in both the deposition rate and the resultant carbon doped SiO₂ film quality is achieved. Optionally, He, Kr, Ne, or Xe may be employed as an inert gas in place of Ar. In particular, film density, hardness, tensile strength, and film thickness uniformity are increased. Preferably, the flow rate ratio of O₂:Ar:2MS/3MS/4MS is about 1:1.5:6 to generate a carbon doped SiO₂ film having a k value of approximately 3.0 and to achieve a higher film quality. However, the magnitude of the Ar flow rate is also a crucial factor since it influences the dielectric constant (k value) of the resulting carbon doped SiO₂ film.

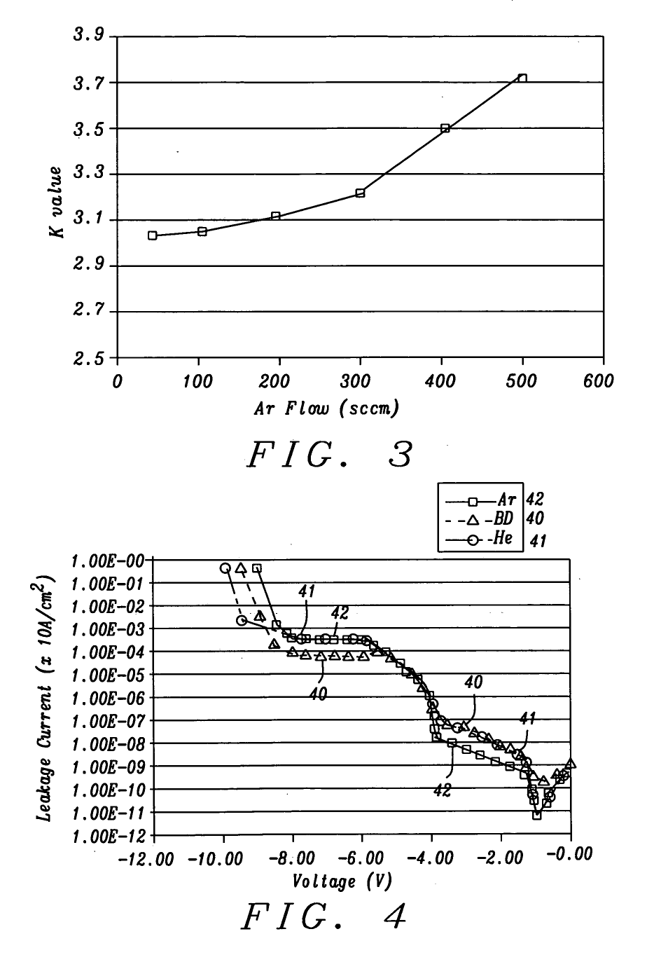

Referring to FIG. 3, the Ar flow rate during the PECVD deposition of a Black Diamond film is shown to have an effect on the resulting dielectric constant of the deposited layer. The data in the plot was generated with a process that included a 3MS flow rate of 600 sccm, an O₂ flow rate of 100 sccm, a chamber temperature of 350° C., a RF power of 600 Watts, and a chamber pressure of 2.5 Torr. Under these conditions, an Ar flow rate of between 50 and 300 sccm is needed to achieve a k value in the range of 3 to about 3.2. At higher Ar flow rates, the k value increases to an unacceptable level. At lower Ar flow rates, the film becomes more porous and less dense. However, in all cases where an Ar flow is present, a more uniform plasma is believed to form above the wafer which helps to produce a more uniform film thickness. The inventors have also found that although a lower temperature increases the deposition rate, a more porous film is formed. Therefore, prior art methods that prefer a carbon doped SiO₂ deposition below 300° C. are generating a porous film in order to lower the k value below 3. However, such procedures usually require a post-treatment that may include an anneal at a temperature above 300° C. and a plasma treatment to densify the film. With the deposition method of the present invention that is preferably performed at a temperature in the range of about 300° C. to 400° C., no post-treatment is needed for a carbon doped SiO₂ layer since a high film density and an acceptable k value are obtained in one step.

Although the inventors are not bound to this theory, they postulate that the sputtering action of the energized Ar molecules and ions in the plasma is crucial because it speeds up the migration of the reactive silicon species and the reactive oxygen species along the surface of the substrate and thereby increases the rate of reaction. Another benefit is that the frequency of PM cleaning operations in the CVD chamber is decreased from once per every 1000 wafers to once per 1500 wafers because film thickness uniformity is kept in a 1 to 2.5% range for a greater number of wafers. For example, after a Black Diamond film is deposited on 1000 wafers in a prior art process without Ar, the film uniformity of the last wafer is 2.9% while for the same number of wafers in a Black Diamond deposition of the present invention, film uniformity is 1.5% for the last wafer. This advantage is believed to result in part from a faster reaction so that each wafer spends less time in the CVD chamber and the Black Diamond deposit on the chamber walls builds up more slowly.

Table 1 shows that the composition of a Black Diamond film is unaffected by adding an inert gas in the deposition process. X-ray photoelectron spectroscopy (XPS) results were obtained from incident angles of 0 and 60 degrees. Note that the analysis shows only C, Si, and O values since H content was not measured. The Black Diamond (BD) layer formed with Ar gas (Ar-BD) and the Black Diamond layer formed with an added He gas (He-BD) were deposited with a process comprising a 150 sccm flow rate of inert gas. Otherwise, process conditions were the same for all samples and included a 350° C. chamber temperature, a RF power of 600 Watts, a chamber pressure of 2.5 Torr, an oxygen flow rate of 100 sccm and a 3MS flow rate of 600 sccm. The slight differences in O, C, and Si content among the three samples are believed to be within experiment error. Thus, no measurable change in BD composition is detected when an inert gas is used in the deposition process. It is understood that the XPS measurement error is about ±2%.

TABLE 1
XPS Results of Black Diamond layers

| | 0° Take off angle | | | 60° Take off angle | | |
|---|---|---|---|---|---|---|
| Material | O | C | Si | O | C | Si |
| Ar-BD | 33.1 | 31.8 | 35.1 | 33.4 | 34.0 | 32.6 |
| He-RD | 34.7 | 30.9 | 34.4 | 34.3 | 33.1 | 32.7 |
| BD | 33.6 | 31.6 | 34.8 | 33.1 | 33.2 | 33.8 |

Still another benefit of incorporating Ar into a carbon doped SiO₂ deposition is that the Ar has a bombardment effect which densifies the low k dielectric layer, improves hardness, and increases its tensile strength as indicated by an increase in Young's Modulus. For example, the density of the BD film in Table 1 is 1.55 gm/cm³ while the Ar-BD film has an increased density of 1.63 gm/cm³. Table 2 below indicates that hardness and Young's Modulus as measured by an MTS Nano Indentor are higher in an Ar-BD film compared with a conventional Black Diamond film formed at either a 350° C. or a 425° C. deposition temperature. An increase in refractive index is also observed for an Ar-BD film which indicates a higher film density and a higher hardness.

TABLE 2
Mechanical Properties of Black Diamond layers

| | 350° C. Deposition | | 425° C. Deposition | |
|---|---|---|---|---|
| | Hardness | Young's Modulus | Hardness | Young's Modulus |
| Material | (GPa) | (Ksi) | (GPa) | (Ksi) |
| Ar-BD | 2.42 | 16.8 | 3.12 | 19.4 |
| BD | 1.76 | 11.6 | 2.29 | 13.7 |

Other advantages of a carbon doped SiO₂ layer formed by the method of this invention will become apparent during a description of FIGS. 5-9 in which a low k dielectric layer is deposited on a substrate and incorporated into a fabrication scheme to form a metal interconnect.

Referring to FIG. 5, a substrate 50 is shown that is typically silicon but may also be based on silicon-on-insulator, Si—Ge, or other compositions commonly employed in the art. In one embodiment, the substrate 50 is comprised of a conductive layer 51 which may be Cu, Al, W, or an Al/Cu alloy. The top of the conductive layer 51 has been planarized to be coplanar with the top surface of substrate 50. The conductive layer 51 may be enclosed on the sides and bottom by a thin diffusion barrier layer (not shown). Furthermore, the substrate 50 may include active and passive devices. An etch stop layer 52 comprised of silicon carbide, silicon nitride, or silicon oxynitride is preferably deposited on substrate 50 in order to protect the conductive layer 51 during subsequent processing steps.

A carbon doped SiO₂ material is deposited by a PECVD method 53 to form a low k dielectric layer 54 on the etch stop layer 52. The low k dielectric layer 54 has a thickness of about 4000 to 8000 Angstroms and is formed in a CVD process chamber in a CVD tool from Applied Materials or Novellus, for example, according to a method of the present invention. Note that the CVD tool may contain multiple process chambers and a means for transporting a wafer between the chambers without exposure to air.

The PECVD method 53 is preferably comprised of a 50 to 300 sccm O₂ flow rate, a 400 to 800 2MS, 3MS, or 4MS flow rate, a 50 to 300 sccm inert gas flow rate, a chamber temperature between about 300° C. and 400° C., a chamber pressure of 1.5 to 4 Torr, and a RF power of from 600 to 800 Watts. More preferably, the deposition conditions are a 100 sccm O₂ flow rate, a 600 sccm 3MS flow rate, a 150 sccm Ar flow rate, a chamber pressure of 2.5 Torr, a chamber temperature of 350° C., and a RF power of 600 Watts. During the PECVD method 53, the low k dielectric layer 54 is deposited at the rate of about 5000 to 8000 Angstroms per minute. This deposition rate represents an increased throughput over a similar method where Ar is omitted from the PECVD process. In an alternative embodiment, He, Ne, Kr, or Xe may be used in place of Ar as the inert gas component in the PECVD method 53.

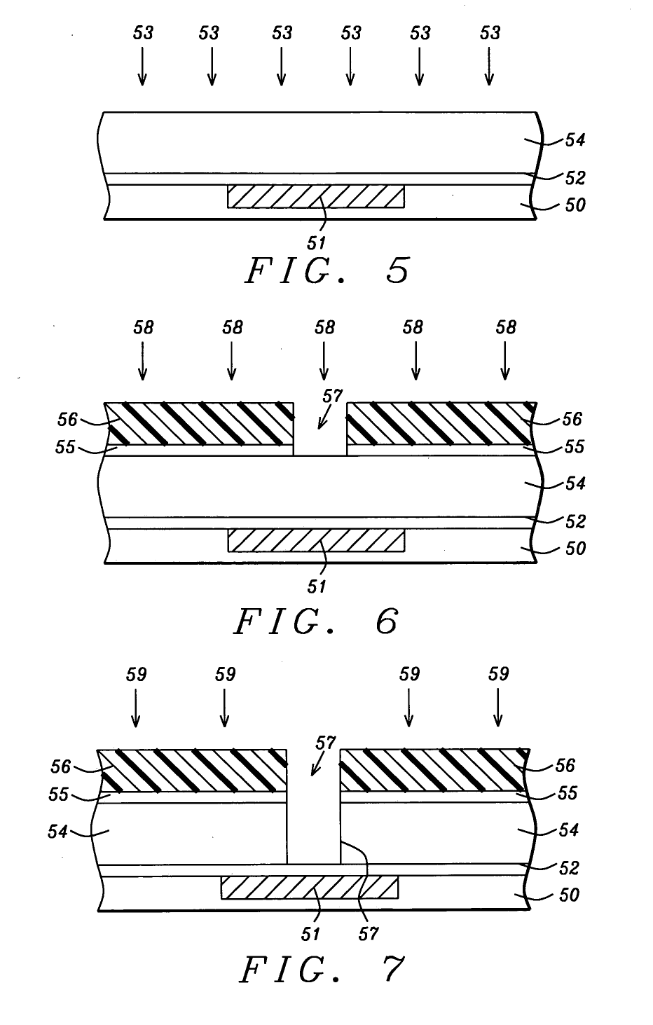

Referring to FIG. 6, the temperature and pressure in the CVD process chamber are returned to acceptable levels and the substrate 50 with a dielectric stack comprised of the etch stop layer 52 and the low k dielectric layer 54 is removed for further processing. In one embodiment, the next step involves deposition of a cap layer 55 which preferably occurs in the same CVD tool used to form the low k dielectric layer 54. A cap layer 55 such as silicon nitride or silicon carbide serves to protect the low k dielectric layer 54 during subsequent process steps to form a metal interconnect in the low k dielectric layer. When the cap layer 55 is silicon oxynitride, the cap layer may also function as an anti-reflective coating (ARC) to improve process latitude in a subsequent patterning step. Alternatively, the cap layer 55 may be used solely as an ARC in which case an organic ARC may be formed by a spin coating and baking procedure at a separate coating station outside the CVD tool or an inorganic ARC may be deposited in a process chamber within the CVD tool.

Next, a first photoresist layer 56 is coated and patterned by conventional methods to form an opening 57. In the exemplary fabrication scheme, the opening 57 is a via which is aligned above the conductive layer 51. However, the opening 57 may be a contact hole or trench in a single damascene scheme. Other openings (not shown) are typically formed in a variety of patterns in the first photoresist layer 56. The opening 57 is transferred through the cap layer 55 with a plasma etch step known to those skilled in the art. In a subsequent etch step 58, a plasma which is usually based on a fluorocarbon gas is generated to transfer the opening 57 through the low k dielectric layer 54.

Referring to FIG. 7, the etch step 58 stops on the etch stop layer 52. An oxygen ashing step 59 is then used to remove the first photoresist layer 56. Note that the low k dielectric layer 54 that forms the sidewalls of the via is exposed to the oxygen plasma which has a tendency to increase the dielectric constant slightly by removal of some C and H atoms from the carbon doped SiO₂ layer. However, the increase in dielectric constant from 3.1 to 3.3 in the low k dielectric layer 54 formed by the present invention is much less than the change from 3.1 to 3.6 for a carbon doped SiO₂ layer which has been deposited by a process that does not include Ar or an inert gas or a post deposition treatment. The higher hardness and film density of the low k dielectric layer 54 of the present invention helps to minimize the effect of oxygen radicals on the low k dielectric layer. In the embodiment where the cap layer 55 is an organic ARC, the cap layer 55 is also removed in the O₂ ashing step 59. In a single damascene scheme, the exposed portion of the etch stop layer 52 is removed at this point and a conformal diffusion barrier layer and metal layer are sequentially deposited in the opening 57.

Referring to FIG. 8, the formation of a metal interconnect in a dual damascene scheme proceeds with formation of a second photoresist layer 60 on the cap layer 55. Optionally, when an organic ARC is removed in the previous ashing step, a new cap layer 55 may be formed by coating and baking a commercially available ARC material before the second photoresist layer 60 is coated. Alternatively, an inert plug (not shown) may be deposited to fill the via 57 before the second photoresist is coated in order to provide a more uniform film thickness of the second photoresist layer 60 and a larger process latitude during the following patterning step. The second photoresist layer 60 is patterned by a conventional method to form a trench 61 aligned above the via 57. It is understood that while the trench 61 is shown above a single via 57, other designs (not shown) are possible in which a trench is formed above two or more vias.

The increased hardness of the low k dielectric layer 54 is valuable in the following step which is a plasma etch transfer of the trench 61 into the low k dielectric layer. In the embodiment where a Black Diamond layer is deposited as the low k dielectric layer 54 and a fluorocarbon based plasma is employed for the trench etch, the decrease in etch rate from 2780 Angstroms/min. for a conventional Black Diamond film to 1780 Angstroms/min. for an Ar-BD film deposited by the method of the present invention allows a better control of the trench 61 depth in the low k dielectric layer 54. Less trench depth variation leads to a more consistent thickness of the metal layer that is deposited in a subsequent step. As a result, a metal interconnect is fabricated with higher performance because of smaller sheet resistance (Rs) variations.

Once the trench 61 has been etched to an acceptable depth in the low k dielectric layer 54, the second photoresist layer 60 and the optional organic cap layer 55 are removed by another O₂ ashing step 62. Again, the low k dielectric layer 54 is subjected to oxygen radicals that may remove some C and H atoms from the low k dielectric layer. However, the k value of a Black Diamond film deposited by the method of the present invention changes from about 3.1 to 3.3 while a conventional Black Diamond film formed without an inert gas and a post treatment step exhibits a k value increase from 3.1 to 3.6. Next, the etch stop layer 52 is preferably removed by a plasma etch process that is well known to those who practice the art.

In an alternative embodiment where the cap layer 55 is an inorganic layer, the cap layer 55 may remain on the low k dielectric layer 54 in order to function as a stop layer in a subsequent planarization process.

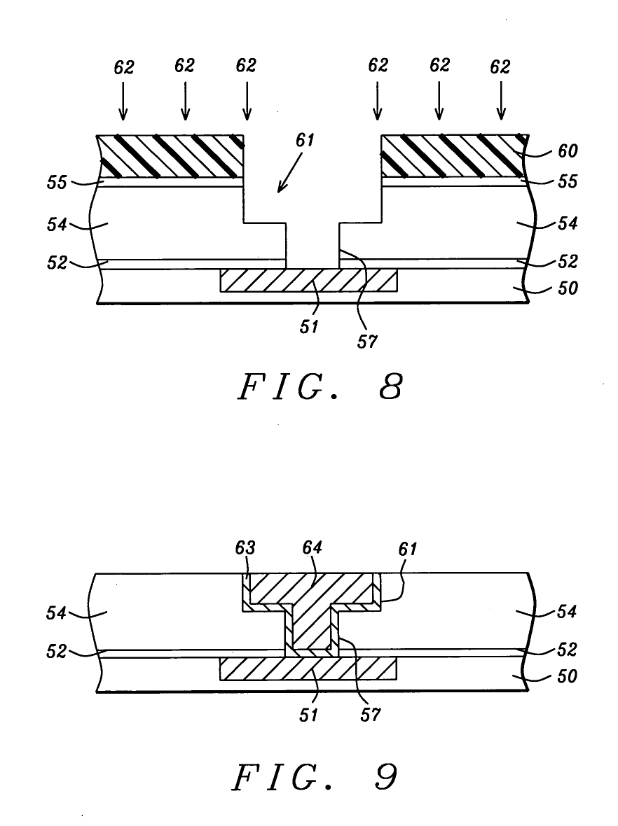

Referring to FIG. 9, the fabrication of a metal interconnect is completed by a sequence in which a diffusion barrier layer 63 is deposited on the sidewalls and bottom of the trench 61 and via 57, a metal layer 64 is deposited to fill the trench 61 and via 57, and a planarization process is used to lower the level of the metal layer 64 which becomes coplanar with the top of the low k dielectric layer 54. An inorganic cap layer 55 may be removed during the planarization process which is a chemical mechanical polish method, for example. The increased hardness in the low k dielectric layer 54 is an advantage during the planarization process since fewer scratches and a smaller amount of dishing is formed on the surface of the low k dielectric layer. Additionally, the low k dielectric layer formed by the present invention exhibits less cracking during the process of forming a metal interconnect because of a higher Young's Modulus than a conventional low k dielectric layer.

Another advantage of incorporating a carbon doped SiO₂ layer as an interlevel dielectric layer (ILD) or intermetal dielectric layer (IMD) is a lower leakage current and a higher breakdown voltage in the resulting device. FIG. 4 shows the results of the leakage current with different applied voltages for a device with a conventional Black Diamond (BD) layer (curve 40), a device with a BD layer formed with a He gas in the deposition (curve 41), and a device with a BD layer formed with Ar in the deposition process (curve 42). The leakage current is less in a device with the Ar-BD layer at an applied voltage range between 1 and 6 volts which is a typical operating range for most devices.

While this invention has been particularly shown and described with reference to, the preferred embodiments thereof, it will be understood by those skilled in the art that various changes in form and details may be made without departing from the spirit and scope of this invention.

1. A method of depositing a carbon doped SiO₂ film on a substrate, comprising:
(a) providing a substrate;
(b) flowing oxygen, an inert gas, and one of dimethylsilane (2MS), trimethylsilane (3MS), and tetramethylsilane (4MS) over said substrate;
(c) generating a plasma to deposit a carbon doped SiO₂ film at certain reaction conditions; and
(d) continuing said deposition until an acceptable film thickness of said carbon doped SiO₂ film is reached.

2. The method of claim 1 wherein said carbon doped SiO₂ film is Black Diamond, CORAL, or HOSP.

3. The method of claim 1 wherein oxygen is flowed with 3MS and Ar as the inert gas in step (b).

4. The method of claim 3 wherein the O₂ flow rate is from about 50 to 300 sccm, the 3MS flow rate is between about 400 and 800 sccm, and the Ar flow rate is between about 50 and 300 sccm.

5. The method of claim 1 wherein the inert gas is He, Kr, Ne, or Xe.

6. The method of claim 1 wherein said certain reaction conditions in step (c) are a temperature between about 300° C. and 400° C., an RF power from about 600 to 800 Watts, and a pressure between about 1.5 and 4 Torr.

7. The method of claim 3 wherein the flow rate ratio of O₂:Ar:2MS/3MS/4MS is about 1:1.5:6.

8. The method of claim 1 wherein the acceptable thickness is from about 4000 to 8000 Angstroms.

9. The method of claim 1 wherein steps (b) to (d) are performed in a CVD process chamber.

10. The method of claim 1 wherein the deposition rate of said carbon doped SiO₂ film is from about 5000 to 8000 Angstroms per minute.

11. A method of forming a metal interconnect on a substrate, comprising:
(a) providing a substrate and an etch stop layer formed on said substrate;
(b) flowing oxygen, an inert gas, and one of dimethylsilane (2MS), trimethylsilane (3MS), and tetramethylsilane (4MS) over said etch stop layer and said substrate;
(c) generating a plasma at certain conditions to deposit a low k dielectric layer comprised of carbon doped SiO₂ on said etch stop layer;
(d) forming an opening in said low k dielectric layer that extends through said etch stop layer; and
(e) depositing a metal layer on said low k dielectric layer that fills said opening.

12. The method of claim 11 further comprised of planarizing said metal layer with a CMP process.

13. The method of claim 11 wherein said etch stop layer is comprised of silicon nitride, silicon oxynitride, or silicon carbide.

14. The method of claim 11 wherein said low k dielectric layer is comprised of Black Diamond, CORAL, or HOSP.

15. The method of claim 11 wherein oxygen is flowed with 3MS and Ar as the inert gas in step (b).

16. The method of claim 15 wherein the O₂ flow rate is from about 50 to 300 sccm, the 3MS flow rate is between about 400 and 800 sccm, and the Ar flow rate is between about 50 and 300 sccm.

17. The method of claim 11 wherein the inert gas is He, Kr, Ne, or Xe.

18. The method of claim 16 wherein the O₂ flow rate is from about 50 to 300 sccm, the 3MS flow rate is between about 400 and 800 sccm, and the Ar flow rate is between about 50 and 300 sccm.

19. The method of claim 11 wherein said certain conditions in step (c) are a temperature between about 300° C. and 400° C., an RF power from about 600 to 800 Watts, and a pressure between about 1.5 and 4 Torr.

20. The method of claim 11 wherein the flow rate ratio of O₂:Ar:2MS/3MS/4MS is about 1:1.5:6.

21. The method of claim 11 wherein the thickness of said low k dielectric layer is from about 4000 to 8000 Angstroms.

22. The method of claim 11 wherein the deposition rate of said low k dielectric layer is from about 5000 to 8000 Angstroms per minute.

23. The method of claim 11 wherein said opening is a contact hole, a trench, or a trench formed above a via.

24. The method of claim 11 further comprised of forming a cap layer on the low k dielectric layer before forming said opening in the low k dielectric layer.

25. The method of claim 24 wherein the cap layer is comprised silicon nitride, silicon oxynitride, or silicon carbide.

26. The method of claim 24 wherein the cap layer is an organic anti-reflective coating (ARC).

27. The method of claim 11 wherein said metal layer is comprised of copper.

28. The method of claim 11 wherein said low k dielectric layer deposition is performed in a CVD process chamber.
